(19) United States
(12) Patent Application Publication
(10) Pub. No.: US 2005/0221617 A1
(43) Pub. Date: Oct. 6, 2005

(54) Inductively coupled plasma chamber attachable to a processing chamber for analysis of process gases

(76) Inventor: Neal R. Rueger, Boise, ID (US)

Correspondence Address: WONG, CABELLO, LUTSCH, RUTHERFORD & BRUCCULERI,;P.C., 20333 SH 249, SUITE 600, HOUSTON, TX, 77070, US

(21) Appl. No.: 10/814,985

(22) Filed: Mar. 31, 2004

(51) Int. Cl. H01L 21/302

(52) U.S. Cl. 438/706; 216/59; 216/61; 156/345.28; 156/345.29

(57) ABSTRACT

Disclosed herein are exemplary embodiments of an improved Inductively Coupled Plasma (ICP) chamber which is externally coupleable to a processing chamber to monitor processes gases therefrom. The disclosed ICP chamber design is beneficial because it allows for the porting of reference gases for the purpose of performing actinometry, and/or allows for the introduction of plasma probes into the plasma within the ICP chamber, both of which improve the reliability of process gas concentration determinations. Also disclosed is a processing system for interfacing the ICP chamber to the processing chamber and for controlling both.

### FIELD OF THE INVENTION

This invention relates to an improved inductively coupled plasma chamber externally coupleable to a processing chamber for the analysis of process gases.

### BACKGROUND

A need exists in the art of semiconductor processing to accurately analyze the components and concentration of process gases used in etching and deposition processes. For example, by analyzing etch byproduct gases in an etching chamber as a function of time, it may be determined when one layer on a semiconductor wafer has been completely etched and another underlying layer of a different composition has started to be etched, a so-called “end point detection” technique. In another example, by analyzing the gases in a deposition chamber, it can be determined whether the deposition chemistry is optimal or perhaps needing adjustment.

In many cases, analysis of such gases is performed “downstream.”—i.e., at some point along the exhaust line from which gases exit the processing chamber. Such an exemplary system is shown in FIG. 1. In this system, a process chamber 10 is ultimately connected to an Inductively Coupled Plasma (ICP) chamber 18 along the chamber's exhaust line. The ICP chamber 18, as is known, induces a plasma in the exhaust gases using a low power RF generator 20. As such, the exhaust gases are ionized (i.e., excited) and eventually relax, thereby emitting photons (i.e., electromagnetic radiation or light). A given gaseous species will emit photons at certain known wavelengths, and therefore by looking at the location of peaks in the emission spectrum for the exhaust gases and their magnitudes, the component species in the exhaust gases and their quantities can be inferred.

In the system of FIG. 1, such optical analysis is accomplished by coupling some portion of the photons in the excited plasma through an optical window in the ICP chamber 18 to an optical fiber 26, which carries the photons to an optical spectrometer 24 for analysis. A computer 22 is used to assess the location and intensity of peaks in the emission spectra provided by the optical spectrometer 24, and if necessary to control the process chamber 10 in response. For example, if the computer 22 determines that the species have changed appreciably, it may determine that an end point has been reached in an etch and that the process chamber 10 should be turned off or modified accordingly (e.g., by introducing new etchant gases or by providing purging gases to the process chamber).

One example of an ICP chamber 18 usable within the context of FIG. 1 is the Candela™ Downstream Plasma Monitoring System, produced by Lightwind Corporation of San Francisco, Calif., which is illustrated in the following article, submitted herewith, and which is incorporated herein by reference: Bladimiro Ruiz, Jr. & Herbert E. Litvak, “Investigation of Silicon Trench Etch Chemistry Using a Downstream Chemical Monitor,” 4th AVS Int'l Conference on Microelectronics and Interfaces (2003).

Traditional ICP chambers 18, however, are not optimal and are potentially subject to providing an erroneous optical analysis of the processing gases, in no small part because factors other than gas concentrations can affect the magnitudes of spectral peaks of the analyzed gases. For example, the “temperature” of the excited electrons in the plasma, indicative of the electron's kinetic energy, will also affect spectral peak magnitudes. Electron temperature is ultimately affected by factors other than gas concentrations, such as variations in pressure. Thus, if pressure inadvertently increases, the electron temperature may decrease, which can influence the relative magnitudes of individual peak intensities. Absent knowledge of the decrease in electron temperature, the system of FIG. 1 might erroneously conclude that the relative concentrations of gases had changed when in fact they had not.

In short, knowledge of electron temperature, or similar variables, can improve the accuracy of the analysis of the composition and quantities of gases present in a sample, as is well known. One such means for measuring electron temperature is the use of a probe (e.g., a Langmuir probe). Such probes come in many forms, but in one embodiment, shown in FIG. 2, the probe 30 consists of a metal wire 34 (usually tungsten or platinum) which has an exposed tip. The bulk of the wire 34 is covered by an insulating material 32, which is usually ceramic. The surface area of the exposed tip of the wire 34 is known, and the wire is biased using a DC power supply 36. By placing a positive voltage on the power supply 36, the electron density in the gas (and hence, its temperature or energy) will register as a current on ammeter 38. Likewise, by placing a negative voltage on the power supply 36, the density of positively charged species (i.e., the positively ionized gas components in the plasma, be they atoms or molecules) can similarly be measured, which like electron temperature can also be used to improve the accuracy of the characterization of the gases.

However, while the use of plasma probes 30 are a known way of characterizing the physics of a plasma, such probe measurements are believed in the prior art to have been taken only within the processing chamber 10 itself, i.e., within a plasma struck in the chamber that processes a semiconductor wafer or other workpiece. Articles disclosing the use of such intra-processing chamber probing techniques can be found in the following articles, all of which are incorporated herein by reference: Freddy Gaboriau et al., “Langmuir Probe Measurements in an Inductively Coupled Plasma: . . . ,” J. Vac. Sci. Technol., Vol. A20 (3), pp. 919-27 (May/June 2002); V. Kaeppelin et al., “Ion Energy Distribution Functions and Langmuir Probe Measurements in Low Pressure Argon Discharges,” J. Vac. Sci. Technol., Vol. A20 (2), pp. 526-29 (March/April 2002); M. V. Malyshev et al., “Diagnostic Studies of Aluminum Etching in an Inductively Coupled Plasma System: . . . ,” J. Vac. Sci. Technol., Vol. A18 (3), pp. 849-59 (May/June 2000); D. M. Manos et al., “Characterization of Laboratory Plasmas With Probes,” J. Vac. Sci. Technol., Vol. A3 (3), pp. 1059-66 (May/June 1985); and S. M. Rossnagel et al., “Langmuir Probe Characterization of Magnetron Operation,” J. Vac. Sci. Technol., Vol. A4 (3), pp. 1822-25 (May/June 1986). Of course, such intra-processing chamber plasma probing techniques are only useful when the process being run in the chamber 10 is a plasma-based process, such as a plasma-based or -enhanced etch or deposition. (For example, it would have no utility to non-plasma-enhanced chemical vapor deposition (CVD) techniques). In any event, traditional ICP chambers 18 like those disclosed in FIG. 1 are not believed to have previously incorporated the use of a plasma probe.

Another technology that can further improve the optical characterization of a plasma is known as actinometry. In actinometry, a gas not otherwise useful in the process (a “reference gas”) is introduced into the plasma at a known rate and in known quantities. A suitable reference gas is preferably inert as concerns the process at issue and has a similar ionization cross-section or excitation cross-section to the gas species that are to be measured, as is known. For example, if Fluorine chemistries are to be characterized, Argon works well as a reference gas. Using Argon, the optical intensities of the peaks in the emission spectrum can be analyzed to more accurately understand the quantities of Fluorine species. If it is seen that the intensity of Argon peaks in the spectrum changes as the intensity of Fluorine peaks change, then it can be inferred that the change in fluorine intensity is not indicative of a change in concentration of the Fluorine, but instead that something else is occurring having the propensity to affect all emission intensities simultaneously (such as a change in electron temperature, a point which can be verified through the use of a plasma probe such as those noted above). However, if the intensity of Fluorine peaks change while the intensity of the Argon peaks stay constant, then it can be accurately inferred that the quantities of Fluorine are in fact changing.

However, while actinometry is a known way of characterizing the physics of a plasma, actinometry, like plasma probing, is believed in the prior art to have been performed only within the processing chamber 10 itself, i.e., as applied to a plasma struck in the chamber that processes a wafer or other workpiece. Articles disclosing the use of such intra-processing chamber actinometry can be found in the following articles, all of which are incorporated herein by reference: Terry A. Miller, “Optical Emission and Laser-Induced Fluorescence Diagnostics,” J. Vac. Sci. Technol., Vol. A4 (3), pp. 1768-72 (May/June 1986); V. M. Donnelly, “A Simple Optical Emission Method for Measuring Percent Dissociations of Feed Gases in Plasmas: . . . ,” J. Vac. Sci. Technol., Vol. A14 (3), pp. 1076-87 (May/June 1996); A. D. Kuypers et al., “Emission Spectroscopy and Actinometry in a Magnetized Low Pressure Radio Frequency Discharge,” J. Vac. Sci. Technol., Vol. A8 (5), pp. 3736-45 (September/October 1990); and Zhimin Wan et al., “Electron Cyclotron Resonance Plasma Reactor for SiO₂ Etching: . . . ,” J. Vac. Sci. Technol., Vol. A13 (4), pp. 2035-43 (July/August 1995). Of course, intra-processing chamber actinometry is only useful when the process being run in the chamber 10 is a plasma-based process. In any event, traditional ICP chambers 18 like those disclosed in FIG. 1 are not believed to have incorporated the technique of actinometry, despite its ability to improve the accuracy of optical gas analysis.

Gas analysis chambers coupleable to production processing chambers 10, such as ICP 18, are beneficial in a production environment because they can provide some degree of analysis of gas composition and quantity in the processing chamber 10. However, production processes continue to grow more sophisticated, and monitoring gas-based production processes within strict tolerances has become increasingly critical as the semiconductor industry pushes toward the fabrication of nanometer-sized structures. But traditional externally-coupleable ICP chambers 18 are relatively simple in design and are growing incapable of providing such needed accuracy. At the same time, it is difficult to employ actinometry and/or plasma probing in a production environment. For example, the gases used for actinometry may interfere with the process that is being run in the processing chamber 10. Likewise, probing creates an impediment and complexity within the processing chamber 10, and gives rise to problems of an additional contamination source, interference with the established processing plasma, increased maintenance, etc.

Accordingly, the art would be benefited by the incorporation of additional gas analysis techniques into ICP chambers externally coupleable to the process chamber under analysis to improve the accuracy of optical measurements they provide.

### SUMMARY

Disclosed herein are exemplary embodiments of an improved Inductively Coupled Plasma (ICP) chamber which is externally coupleable to a processing chamber to monitor processes gases therefrom. The disclosed ICP chamber design is beneficial because it allows for the porting of reference gases for the purpose of performing actinometry, and/or allows for the introduction of plasma probes into the plasma within the ICP chamber, both of which improve the reliability of process gas concentration determinations. Also disclosed is a processing system for interfacing the ICP chamber to the processing chamber and for controlling both.

### BRIEF DESCRIPTION OF THE DRAWINGS

Embodiments of the inventive aspects of this disclosure will be best understood with reference to the following detailed description, when read in conjunction with the accompanying drawings, in which:

FIG. 1 illustrates a conventional ICP chamber coupled to a processing chamber in a processing system.

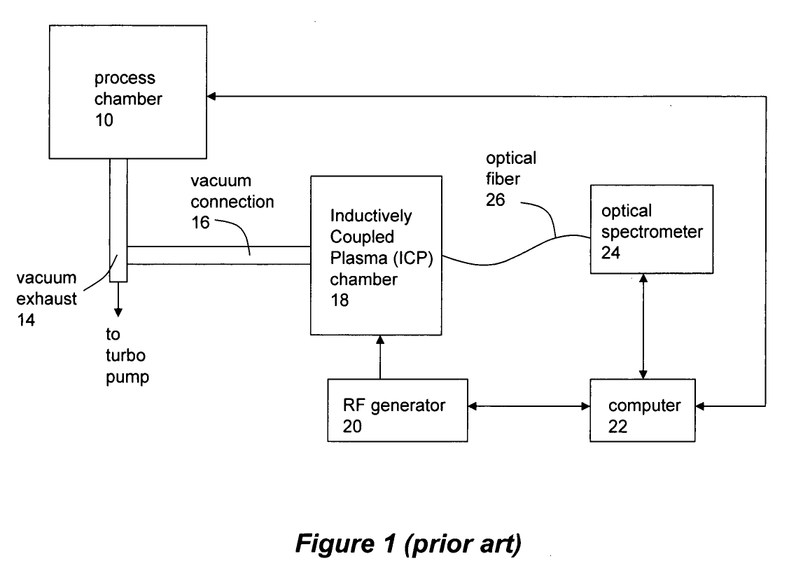

FIG. 2 illustrates a conventional plasma probe.

FIG. 3 illustrates a cross-sectional view of the improved ICP chamber.

FIG. 4 illustrates the improved ICP chamber coupled to a processing chamber in a processing system.

FIG. 5 illustrates the various locations where the improved ICP chamber can be utilized “downstream” from the processing chamber.

### DETAILED DESCRIPTION

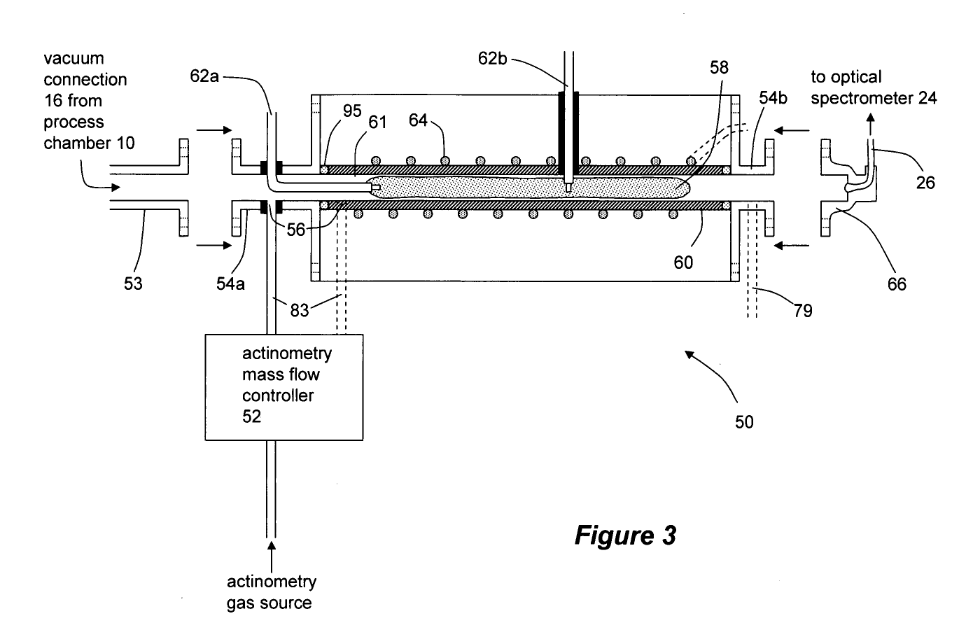

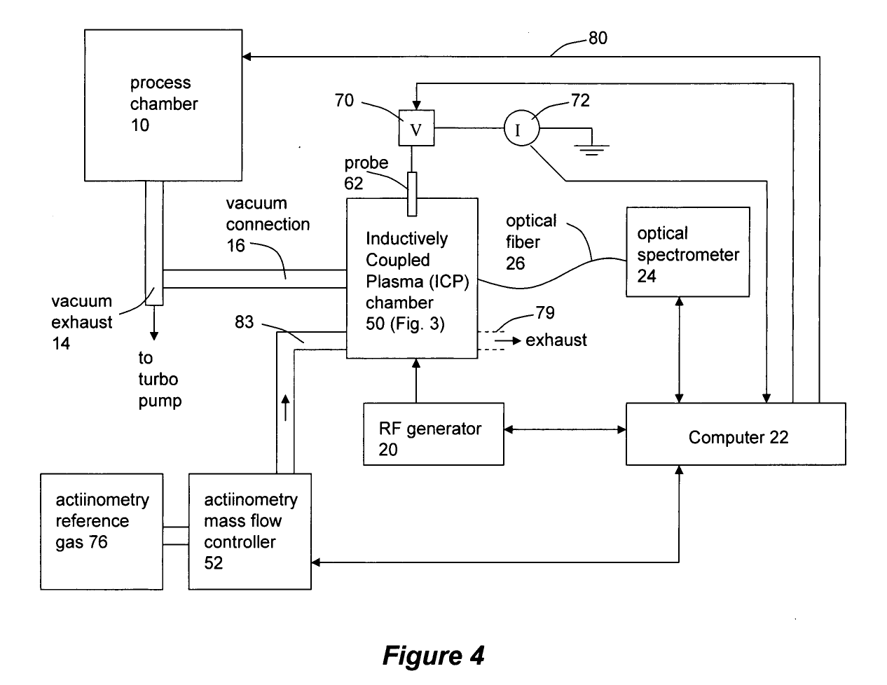

FIG. 3 illustrates a cross-sectional view of the improved ICP chamber 50, while FIG. 4 illustrates the improved ICP chamber 50 coupled to a processing chamber 10 in the context of a production processing system. The ICP chamber 50 is cylindrical and has two flanges 54a and 54b on opposite ends, which are preferably KF40 flanges as are well known in the semiconductor processing arts. Flange 54a is coupleable using bolts and an O-ring (not shown) to a flange 53 ultimately coupled to the processing chamber 10 whose gases are being monitored. Flange 54b is similarly coupleable to a flange 66 which contains an end of the fiber optic cable 26 which sends photons from the ICP chamber 50 to the optical spectrometer 24 for analysis. The inside portions of the flange pieces 54a, 54b comprise end plates boltable to the circular ends of the cylindrical body of the ICP chamber 50.

Internal to the main body of chamber 50 is a cylindrical cavity 61 in which the gases from the processing chamber 10 are excited to form a plasma 58. These gases are excited (ionized) by applying radio frequency (RF) power via RF generator 20 to coils 64 (shown in cross section), which may constitute a helical coil running along the length of the main body and around a dielectric 60. The dielectric 60, such as an aluminum oxide ceramic tube (e.g., alumina), quartz tube, or sapphire tube, etc., lines the cylindrical cavity 61. The dielectric 60 is held in place by the ends plates of the flanges 54a, 54b, and is sealed thereto using O-rings 95. Such details concerning the construction of an ICP chamber are known. In any event, a plasma 58 can be excited in the ICP 50 in any number of ways known in the art, such as through the use of parallel plates. In other words, the plasma chamber 50 need not be cylindrical and its plasma cavity need not be cylindrical.

A port 56 is also present for introducing an actinometric reference gas to the processing gases from the processing chamber 10, hence improving the accuracy of the spectral analysis. Port 56 is coupled by an input line 83 to a mass flow controller 52 for introducing known quantities of the actinometric reference gas 76 (FIG. 4). Port 56 can be located at many different locations on the ICP chamber 50, but in a preferred embodiment ports into the flange 54a closest to the processing chamber 10. In this way, gases from the processing chamber 10 will mix or diffuse with the actinometric reference gas (or gases) prior to introduction into the cylindrical cavity 61 where the plasma 58 is formed. However, port 56 may also port into the main body of the ICP chamber 50, as shown in dotted lines in FIG. 3, although this may require milling a small hole into dielectric 60 to accommodate input line 83 which would then need to be pressure sealed. A gasket or line connection suitable to handle the chemicals and pressures at issue can be used to seal the input line 83 to the port 56, and/or the input line 83 from the mass flow controller 52 may be directly welded to the flange 54a or to the main chamber body.

The processing gases from the processing chamber 10 and the actinometric reference gas from input line 83 will preferably naturally diffuse into the cylindrical cavity 61 of the ICP chamber 50 where they can be excited and optically analyzed. However, an exhaust line 79 coupled to a pump (not shown) can be also used to move this mixture through the cylindrical cavity 61. If gas used, exhaust line 79 is preferably present on the opposing flange 54b, as shown in dotted lines in FIGS. 3 and 4.

As best seen in FIG. 4, the mass flow controller 52 for the actinometric reference gas is preferably controlled by the computer 22 that controls the processing chamber 10 and receives spectral data from the spectrometer 24. Accordingly, the computer 22 knows when it is an appropriate time in the process to start actinometric analysis (i.e., by signaling the mass flow controller 52 to introduce the actinometric reference gas), and knows by monitoring the spectral data from the spectrometer 24 whether the process being run in processing chamber 10 needs adjustment. (The mass flow controller 52 and the actinometric reference gas source 76 may be associated with various valves or purge lines as one skilled in the art will understand, which are not shown).

Accordingly, the computer 22 at an appropriate step during the processing in processing chamber 10 can start actinometric analysis by activating the mass flow controller 52 to introduce the reference gas 76 into the cylindrical cavity 61. Once actinometry has been performed to some end, e.g., improvement of the accuracy of detection of an etch end point, the computer 22 can shut off the mass flow controller 52 (and can possibly modify the process being run in processing chamber 10 if necessary). For example, assume that the ICP chamber 50 is monitoring a Fluorine-based etch occurring in processing chamber 10, and that Argon is used as the actinometric reference gas. Suppose the computer 22 upon receipt of spectral information from the spectrometer 24 sees the magnitude of peaks in the Fluorine-based spectra rising, but also see the magnitude of Argon-based peaks rising. Absent the additional information provided by actinometry (namely, spectral information concerning the Argon reference gas), the computer 22 might erroneously conclude that the concentrations of Fluorine was rising, and accordingly might attempt to take corrective action by reducing input Fluorine gas flows to the chamber 10 (i.e., through processing chamber control line 80). But with the added benefit of the knowledge of the increase in the Argon peaks, the computer 22 can correlate this increase in Fluorine peaks with an increase in the Argon peaks, and perhaps come to the conclusion that the Fluorine concentration does not need reduction, but instead that the pressure in chamber 10 needs to be increased (or that electron temperature has increased).

Although not shown, it should be understood that several ports 56 could be used for the introduction of several different actinometric reference gases. This would allow more than one reference gas to be used in the actinometric assessment of the processing gases, or can allow different reference gases to be used at different times in the process. However, the use of a plurality of ports 56 (and their associated mass flow controllers, etc.) are not shown for clarity.

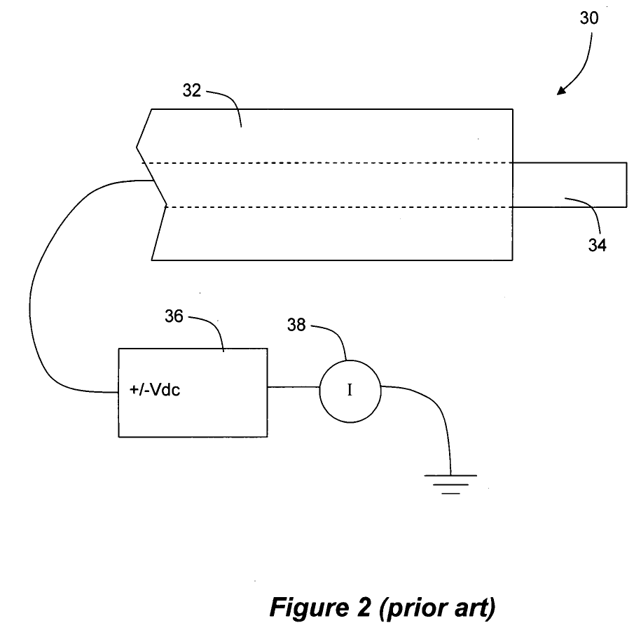

Also present in the improved ICP chamber 50 are plasma probes 62a, 62b, which are preferably similar to the probe disclosed in FIG. 2, but which can comprise other plasma probes known in the art or hereafter developed and useful for analyzing plasmas. As shown, the probes can be introduced into the cylindrical cavity 61 in any number of different ways. For example, probe 62a enters the cavity 61 through a port hole in the flange 54a. Alternatively, probe 62b directly enters the cavity 61 through the main body of the chamber 50. For this orientation, it is important that the probe 62b not interfere with the coil 64 used to strike the plasma 58 or other necessary electronics. Additionally, probe 62b requires that a small hole be milled into the dielectric 60. Both probes 62a or 62b are preferably seated within gaskets suitable to handle the chemicals and pressures at issue.

It may be beneficial to use more than probe 62, as the different orientations of the probe (62a is horizontal; 62b is vertical) may provide different data, or because it may be beneficial to probe the plasma 58 at more than one location to improve its accuracy. However, in the simplest embodiment, only one probe 62 is needed. Additionally the probes 62a and 62b in other embodiments can be made moveable within the cylindrical cavity 61 so that different locations of the plasma 58 can be monitored.

The probe(s) 62 are accompanied in the processing gas analysis system by the use of a DC voltage power supply 70 and an ammeter 72, as best shown in FIG. 4, and which function similarly to like devices in FIG. 2. As incorporated into the system, the computer 22 controls the voltage on voltage supply 70, and receives current readings from ammeter 72 to better understand the influences (e.g., electron temperature) taking place in the plasma 58. For example, suppose the probe(s) 62 register an increase in electron temperature, and the optical spectra from spectrometer 24 evidences an increase in the magnitude of the peaks for the processing gases received from processing chamber 10. Absent knowledge of the increase in electron temperature, computer 22 might erroneously conclude that the concentrations of the gases were rising in the processing chamber 10, and might attempt to take corrective action by reducing input gas flows to the chamber 10 (i.e., through processing chamber control line 80). But with the added benefit of the knowledge of the increase in electron temperature, the computer 22 can correlate this increase with an increase in the peaks, and perhaps come to the conclusion that the input gas flows do not need reduction, but instead that the pressure in chamber 10 needs to be increased.

In short, modification of traditional ICP chambers coupled externally to the processing chamber to include the ability to perform actinometry and plasma probing offer significant advantages to the analysis of processing gases. For a given analysis application, perhaps only one of these techniques (actinometry, probing) would be beneficial or desirable, and hence perhaps only one would be used. In other applications, the benefits provided by both techniques might be necessary, and hence both would be used.

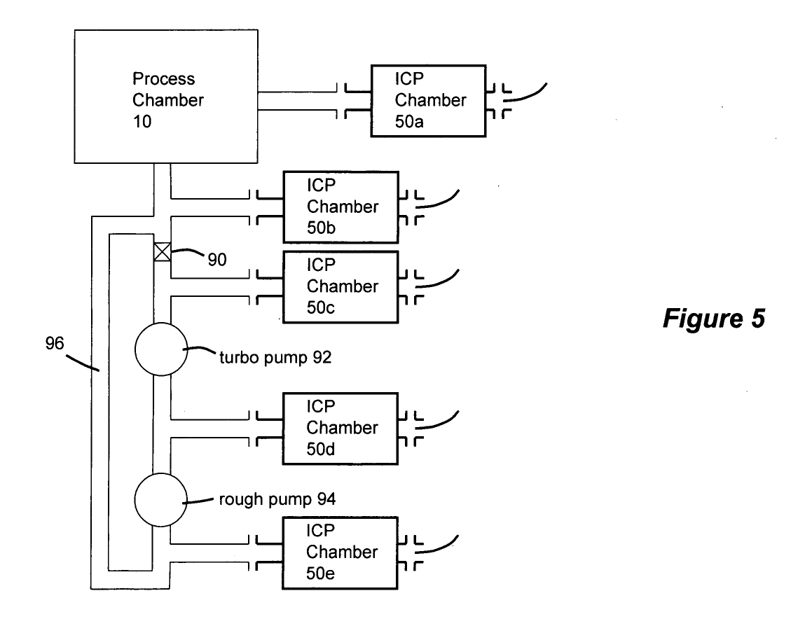

FIG. 5 illustrates the various locations where the ICP chamber 50 can be utilized “downstream” from the processing chamber 10. As shown, the ICP chamber 50 can be coupled directly to the processing chamber 10 (50a); can be coupled between the exhaust port on the processing chamber 10 and the throttle valve 90 (50b); can be coupled between the throttle valve 90 and the turbo pump 92 (50c); can be coupled between the turbo pump 92 and the rough pump 94 (50d); or can be coupled along the roughing line 96 (50e). The addition of actinometric and/or plasma probing techniques can be beneficial in any of these downstream locations, and preferably occurs at pressures ranging from 1 mTorr to 200 Torr.

Additionally, and although not shown, the ICP chamber 50 can be used to analyze the processing gases before they are introduced into the processing chamber 10, although in this circumstance it may be beneficial to ensure that the gases being tested are de-ionized before introduction into the processing chamber 10. Additionally, care should be taken to ensure that any actinometric reference gases introduced “upstream” will not adversely affect the process which will take place in the processing chamber 10.

As noted earlier, the incorporation of actinometry and probing capability into the improved ICP chamber 50 has significant benefits. First, modification to the processing chamber 10 is not necessary, reducing potential sources of contamination and necessary maintenance of the chamber 10. Second, the ICP chamber allows for the analysis of gases used in the processing chamber 10 even when those gases are not ionized (e.g., CVD deposition). Additionally, there is no need to introduce actinometry reference gases or probes into the process chamber, which removes factors from the processing chamber which could adversely affect the sensitive processes being run therein.

“Processing gas” as used herein should be understood as including both gases introduced into the processing chamber 10 to perform a process on a workpiece as well as gaseous products or byproducts stemming from reaction of the introduced gases with the workpiece. Moreover, “processing gas” should not be understood as necessarily comprising only one type of molecule or species. For example, two etching gases introduced into a chamber, or one gas introduced into the chamber and another gas which results from interaction with the workpiece, constitutes a “processing gas,” even though that gas comprises a mixture of more than one type of molecule or species.

Saying that two items are “coupled” does not necessarily imply that the items are in direct contact. Two items can still be functionally coupled even if an intermediary intervenes between them.

It should be understood that the inventive concepts disclosed herein are capable of many modifications. To the extent such modifications fall within the scope of the appended claims and their equivalents, they are intended to be covered by this patent.

1. A plasma chamber coupleable to a processing chamber for assisting in the analysis of at least one processing gas for performing a process in a processing chamber, comprising:
a processing gas inlet port coupleable to the processing chamber for receiving the at least one processing gas from the processing chamber;
at least one reference gas inlet port for receiving at least one reference gas from at least one reference gas source;
a cavity for receiving the at least one processing gas and the at least one reference gas; and
an energy source for exciting the at least one processing gas and the at least one reference gas to form a plasma.

2. The plasma chamber of claim 1, further comprising at least one probe for measuring the energy of at least one species in the plasma.

3. The plasma chamber of claim 1, further comprising an optical window for coupling radiation in the plasma to an optical transmission path coupleable to an spectrometer.

4. The plasma chamber of claim 1, wherein the cavity is cylindrical.

5. The plasma chamber of claim 4, wherein the cavity is lined with a dielectric.

6. The plasma chamber of claim 1, wherein the processing gas inlet port comprises a flange.

7. The plasma chamber of claim 6, wherein the at least one reference gas inlet port is located on the flange.

8. The plasma chamber of claim 1, wherein the at least one reference gas inlet port is proximate to the processing gas inlet port.

9. The plasma chamber of claim 1, further comprising an exhaust line coupled to the cavity.

10. The plasma chamber of claim 1, wherein the plasma is not used as part of the process.

11. A system, comprising:
a processing chamber for performing a process on a workpiece using at least one processing gas; and
a plasma chamber coupled to the processing chamber for assisting in the analysis of at least one processing gas, the plasma chamber comprising:
a processing gas inlet port for receiving the at least one processing gas from the processing chamber;
at least one reference gas inlet port for receiving at least one reference gas from at least one reference gas source;
a cavity for receiving the at least one processing gas and the at least one reference gas; and
an energy source for exciting the at least one processing gas and the at least one reference gas to form a plasma.

12. The system of claim 11, wherein the plasma chamber further comprises at least one probe for measuring the energy of at least one species in the plasma.

13. The system of claim 11, further comprising a spectrometer, wherein the plasma chamber further comprises an optical transmission path for coupling radiation in the plasma to the spectrometer.

14. The system of claim 13, further comprising a computer, wherein the computer analyzes spectral data from the spectrometer.

15. The system of claim 14, wherein the computer modifies the process in response to the spectral data.

16. The system of claim 11, further comprising a computer, wherein the computer controls receiving the at least one reference gas from the at least one reference gas source.

17. The system of claim 11, wherein the plasma chamber further comprises an exhaust line coupled to the cavity.

18. The system of claim 11, wherein the process is selected from the group consisting of deposition and etch.

19. The system of claim 11, wherein the process is selected from the group consisting of a plasma-based process and a non-plasma-based process.

20. The system of claim 11, wherein the plasma chamber is coupled to an exhaust line on the processing chamber.

21. The system of claim 11, wherein the plasma chamber is coupled to the processing chamber via at least a pump or a valve.

22. The system of claim 11, wherein the plasma chamber is directly coupled to the processing chamber.

23. The system of claim 11, wherein the plasma is not used as part of the process.

24. A method for assisting in the analysis of at least one processing gas which performs a process in a processing chamber, comprising:
receiving at a cavity at least one processing gas from the processing chamber;
receiving at the cavity at least one reference gas from at least one reference gas source; and
forming in the cavity a plasma from the received gases.

25. The method of claim 24, further comprising measuring the energy of at least one species in the plasma.

26. The method of claim 24, further comprising coupling radiation in the plasma to an optical transmission path coupleable to a spectrometer.

27. The method of claim 24, wherein the cavity is cylindrical.

28. The method of claim 27, wherein the cavity is lined with a dielectric.

29. The method of claim 24, wherein the at least one processing gas and the at least one processing gas are received at a common location with respect to the cavity.

30. The method of claim 24, further comprising coupling the cavity to an exhaust line.

31. The method of claim 24, wherein the plasma is not used as part of the process.

32. A method for assisting in the analysis of at least one processing gas, comprising:
performing a process on a workpiece in a processing chamber;
receiving at least one processing gas from the processing chamber at a plasma chamber coupled to the processing chamber;
receiving at least one reference gas from at least one reference gas source at a plasma chamber; and
forming in the plasma chamber a plasma from the received gases.

33. The method of claim 32, further comprising measuring the energy of at least one species in the plasma.

34. The method of claim 32, further comprising coupling radiation in the plasma to a spectrometer to form spectral data.

35. The method of claim 34, further comprising modifying the process in response to the spectral data.

36. The method of claim 32, further comprising controlling receiving the at least one reference gas from the at least one reference gas source.

37. The method of claim 32, further comprising exhausting the plasma chamber.

38. The method of claim 32, wherein the process is selected from the group consisting of deposition and etch.

39. The method of claim 32, wherein process is selected from the group consisting of a plasma-based process and a non-plasma-based process.

40. The method of claim 32, wherein the plasma chamber receives the at least one processing gas via an exhaust line on the processing chamber.

41. The method of claim 32, wherein the plasma chamber receives the at least one processing gas from the processing chamber via at least a pump or a valve.

42. The method of claim 32, wherein the plasma chamber directly receives the at least one processing gas from the processing chamber.

43. The method of claim 32, wherein the plasma is not used as part of the process.

44. A plasma chamber coupleable to a processing chamber for assisting in the analysis of at least one processing gas for performing a process in a processing chamber, comprising:
a processing gas inlet port coupleable to the processing chamber for receiving the at least one processing gas from the processing chamber;
a cavity for receiving the at least one processing gas;
an energy source for exciting the at least one processing gas to form a plasma; and
at least one probe for measuring the energy of at least one species in the plasma.

45. The plasma chamber of claim 44, further comprising at least one reference gas inlet port for receiving at least one reference gas from at least one reference gas source, and wherein the energy source is further for exciting the at least one reference gas together with the at least one processing gas to form the plasma.

46. The plasma chamber of claim 44, further comprising an optical window for coupling radiation in the plasma to an optical transmission path coupleable to a spectrometer.

47. The plasma chamber of claim 44, wherein the cavity is cylindrical.

48. The plasma chamber of claim 47, wherein the cavity is lined with a dielectric.

49. The plasma chamber of claim 44, wherein the processing gas inlet port comprises a flange.

50. The plasma chamber of claim 49, wherein the at least one probe enters the cavity through the flange.

51. The plasma chamber of claim 44, wherein the at least one probe enters the cavity through a main body of the plasma chamber.

52. The plasma chamber of claim 44, further comprising an exhaust line coupled to the cavity.

53. The plasma chamber of claim 44, wherein the probe comprises a wire with an exposed tip.

54. The plasma chamber of claim 44, wherein the species is selected from the group consisting of electrons and ionized atoms or molecules.

55. The plasma chamber of claim 44, wherein the plasma is not used as part of the process.

56. A system, comprising:
a processing chamber for performing a process on a workpiece using at least one processing gas; and
a plasma chamber coupled to the processing chamber for assisting in the analysis of at least one processing gas, the plasma chamber comprising:
a processing gas inlet port coupleable to the processing chamber for receiving the at least one processing gas from the processing chamber;
a cavity for receiving the at least one processing gas;
an energy source for exciting the at least one processing gas to form a plasma; and
at least one probe for measuring the energy of at least one species in the plasma.

57. The system of claim 56, wherein the plasma chamber further comprises at least one reference gas inlet port for receiving at least one reference gas from at least one reference gas source, and wherein the energy source is further for exciting the at least one reference gas together with the at least one processing gas to form the plasma.

58. The system of claim 56, further comprising a spectrometer, wherein the plasma chamber further comprises an optical transmission path for coupling radiation in the plasma to the spectrometer.

59. The system of claim 56, wherein the plasma chamber further comprises an exhaust line coupled to the cavity.

60. The system of claim 56, further comprising a computer, wherein the computer analyzes spectral data from a spectrometer.

61. The system of claim 60, wherein the computer modifies the process in response to the spectral data and the measured energy.

62. The system of claim 56, further comprising a computer, wherein the computer controls biasing of the probe.

63. The system of claim 56, wherein the process is selected from the group consisting of deposition and etch.

64. The system of claim 56, wherein the process is selected from the group consisting of a plasma-based process and a non-plasma-based process.

65. The system of claim 56, wherein the plasma chamber is coupled to an exhaust line on the processing chamber.

66. The system of claim 56, wherein the plasma chamber is coupled to the processing chamber via at least a pump or a valve.

67. The system of claim 56, wherein the plasma chamber is directly coupled to the processing chamber.

68. The system of claim 56, further comprising a voltage source for biasing the probe tip, and wherein measuring the energy comprises monitoring a current drawn through the voltage source.

69. The system of claim 56, wherein the species is selected from the group consisting of electrons and ionized atoms or molecules.

70. The system of claim 56, wherein the plasma is not used as part of the process.

71. A method for assisting in the analysis of at least one processing gas which performs a process in a processing chamber, comprising:
receiving at a cavity the at least one processing gas from the processing chamber;
forming a plasma in the received at least one processing gas in the cavity; and
measuring the energy of at least one species in the plasma.

72. The method of claim 71, further comprising receiving at the cavity at least one reference gas from at least one reference gas source.

73. The method of claim 71, further comprising coupling radiation in the plasma to an optical transmission path coupleable to a spectrometer.

74. The method of claim 71, wherein the cavity is cylindrical.

75. The method of claim 74, wherein the cavity is lined with a dielectric.

76. The method of claim 71, wherein measuring the energy of at least one species in the plasma comprises the use of a probe.

77. The method of claim 71, wherein measuring the energy of the at least one species in the plasma comprises biasing a probe and monitoring its current.

78. The method of claim 71, wherein the probe comprises a wire with an exposed tip.

79. The method of claim 71, wherein the at least one probe enters the cavity through a flange.

80. The method of claim 71, wherein the at least one probe enters directly into the cavity.

81. The method of claim 71, wherein the species is selected from the group consisting of electrons and ionized atoms or molecules.

82. The method of claim 71, further comprising coupling the cavity to an exhaust line.

83. The method of claim 71, wherein the plasma is not used as part of the process.

84. A method for assisting in the analysis of at least one processing gas, comprising:
performing a process on a workpiece in a processing chamber;
receiving at a plasma chamber the at least one processing gas from the processing chamber;
forming a plasma in the received at least one processing gas in the plasma chamber; and
measuring the energy of at least one species in the plasma.

85. The method of claim 84, further comprising receiving at the plasma chamber at least one reference gas from at least one reference gas source, and further forming a plasma in the received at least one reference gas in the plasma chamber along with the at least one processing gas.

86. The method of claim 84, further comprising coupling radiation in the plasma to an optical transmission path coupleable to a spectrometer.

87. The method of claim 84, further comprising coupling radiation in the plasma to a spectrometer to form spectral data.

88. The method of claim 87, further comprising modifying the process in response to the spectral data and the measured energy.

89. The method of claim 84, wherein measuring the energy of at least one species in the plasma comprises monitoring current draw through a probe.

90. The method of claim 84, wherein the species is selected from the group consisting of electrons and ionized atoms or molecules.

91. The method of claim 84, further comprising coupling the cavity to an exhaust line.

92. The method of claim 84, wherein the process is selected from the group consisting of etching and depositing.

93. The method of claim 84, wherein the process is selected from the group consisting of a plasma-based process and a non-plasma-based process.

94. The method of claim 84, wherein the plasma chamber receives the at least one processing gas via an exhaust line on the processing chamber.

95. The method of claim 84, wherein the plasma chamber receives the at least one processing gas from the processing chamber via at least a pump or a valve.

96. The method of claim 84, wherein the plasma chamber directly receives the at least one processing gas from the processing chamber.

97. The method of claim 84, wherein the plasma is not used as part of the process.
